(19) United States
(12) Patent Application Publication
(10) Pub. No.: US 2009/0059109 A1
(43) Pub. Date: Mar. 5, 2009

(54) Array substrate and display panel having the same

(76) Inventors: Min-Hyuk Choi, Gyeonggi-do (KR); Chun-Gi You, Gyeonggi-do (KR); Seong-Kweon Heo, Gyeonggi-do (KR)

Correspondence Address: MACPHERSON KWOK CHEN & HEID LLP, 2033 GATEWAY PLACE, SUITE 400, SAN JOSE, CA, 95110, US

(21) Appl. No.: 12/080,270

(22) Filed: Apr. 1, 2008

(30) Foreign Application Priority Data
Aug. 29, 2007 (KR) 2007-87194

(51) Int. Cl. G02F 1/136; H01L 29/04

(52) U.S. Cl. 349/39; 257/71; 257/E29.003

(57) ABSTRACT

An array substrate includes a transistor, a pixel electrode and an upper insulation layer. The transistor is formed on an upper insulation layer formed on a base substrate. The pixel electrode is electrically connected to the transistor. The upper insulation layer covers the transistor to directly make contact with the base substrate of an area having the pixel electrode formed thereon.

### CROSS-REFERENCE TO RELATED APPLICATIONS

This application claims priority under 35 U.S.C. § 119 to Korean Patent Application No. 10-2007-87194, filed on Aug. 29, 2007 in the Korean Intellectual Property Office (KIPO), the contents of which are herein incorporated by reference in their entirety.

### BACKGROUND OF THE INVENTION

1. Field of the Invention

The present invention relates to an array substrate and a display panel having the array substrate. More particularly, the present invention relates to an array substrate for a liquid crystal display (LCD) device and a display panel having the array substrate.

2. Description of the Related Art

Generally, a liquid crystal display (LCD) device includes an LCD panel displaying images using light and a backlight assembly providing the LCD panel with light. Typically, the LCD panel includes an array substrate having a thin-film transistor (TFT) and a pixel electrode formed thereon, a color filter substrate having a color filter formed thereon and a liquid crystal layer interposed between the array substrate and the color filter substrate. The TFT includes a gate electrode, a source electrode, a drain electrode and an active layer.

As LCD devices are being adopted in modern small-size products, the need for enhanced light transmittance is increasing. In order to increase the light transmittance, an organic layer structure in which an organic layer is formed on an array substrate has been developed. The organic layer decreases signal interference between a metal line and a pixel electrode that are formed on the array substrate, and the size to which the pixel electrode is formed is increased to enhance the light transmittance through a high aperture ratio.

However, in the above configuration the light provided from the backlight may be decreased and scattered by the increase in the number of layers that are formed on the array substrate, so that about 5% to about 8% of the light provided from the backlight reaches a user's eyes.

### SUMMARY OF THE INVENTION

The present invention provides an array substrate having an increased light transmittance.

The present invention also provides a display panel having the above-mentioned array substrate.

In one embodiment of the present invention, an array substrate includes a substrate, a first insulation layer, a transistor, a pixel electrode and a second insulation layer. The substrate has a first surface. The first insulation layer is formed on a first portion of the first surface. The transistor is formed in correspondence with the first insulation layer. The pixel electrode is electrically connected to the transistor. The second insulation layer has a first portion on the transistor and a second portion directly contracting the first surface of the surface in an area adjacent to the transistor.

In another embodiment of the present invention, a display panel includes an array substrate and an opposite substrate. The array substrate includes a substrate, a first insulation layer, a transistor, a pixel electrode and a second insulation layer. The substrate has a first surface. The first insulation layer is formed on a first portion of the first surface. The transistor is formed in correspondence with the first insulation layer. The pixel electrode is electrically connected to the transistor. The second insulation layer has a first portion on the transistor and a second portion directly contracting the first surface of the surface in an area adjacent to the transistor. The opposite substrate is coupled to the array substrate to receive a liquid crystal layer. The opposite substrate may include a color filter pattern formed on a second substrate in correspondence with an area having the pixel electrode formed thereon.

According to the array substrate and the display panel having the array substrate, insulation layers formed in a transmissive area are removed, so that the light transmittance of the array substrate may be enhanced.

### BRIEF DESCRIPTION OF THE DRAWINGS

The above and other advantages of the present invention will become readily apparent by reference to the following detailed description when considered in conjunction with the accompanying drawings wherein:

FIG. 1 is a plan view illustrating a display panel according to a first exemplary embodiment of the present invention;

FIG. 2 is a cross-sectional view taken along a line I-I′ of FIG. 1;

FIGS. 3 and 4 are cross-sectional views of stages in a process for manufacturing the array substrate of FIG. 2;

FIG. 5 is a cross-sectional view illustrating a display panel according to a second exemplary embodiment of the present invention;

FIG. 6 is a cross-sectional view schematically illustrating a display panel according to a third exemplary embodiment of the present invention; and

FIG. 7 is a graph showing light transmittances of array substrates according to an exemplary embodiment of the present invention and a comparative embodiment of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

### Exemplary Embodiment 1

### A Display Panel

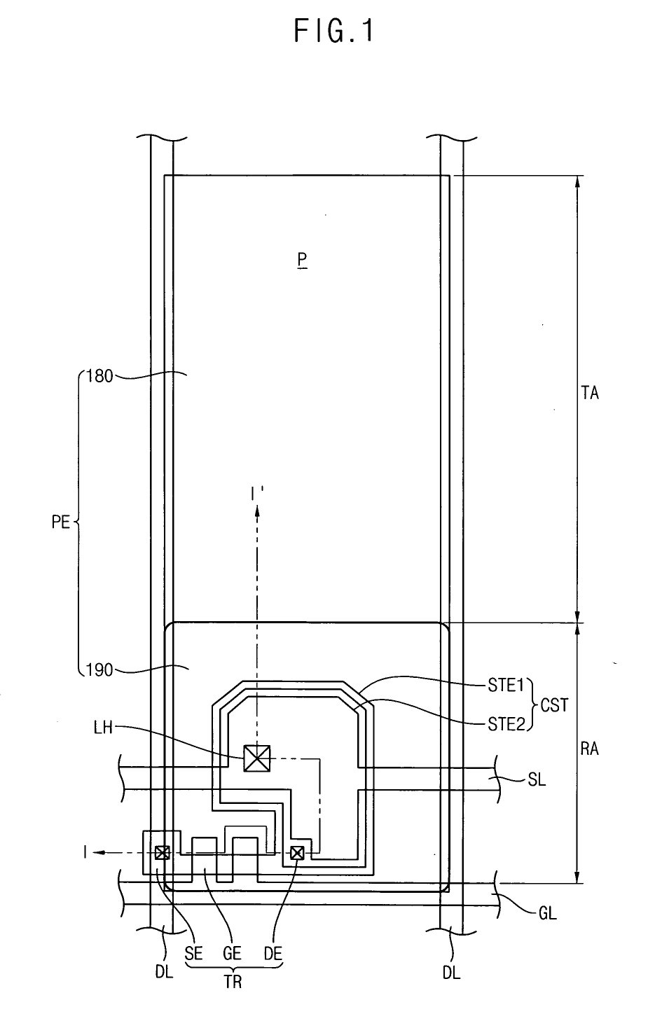

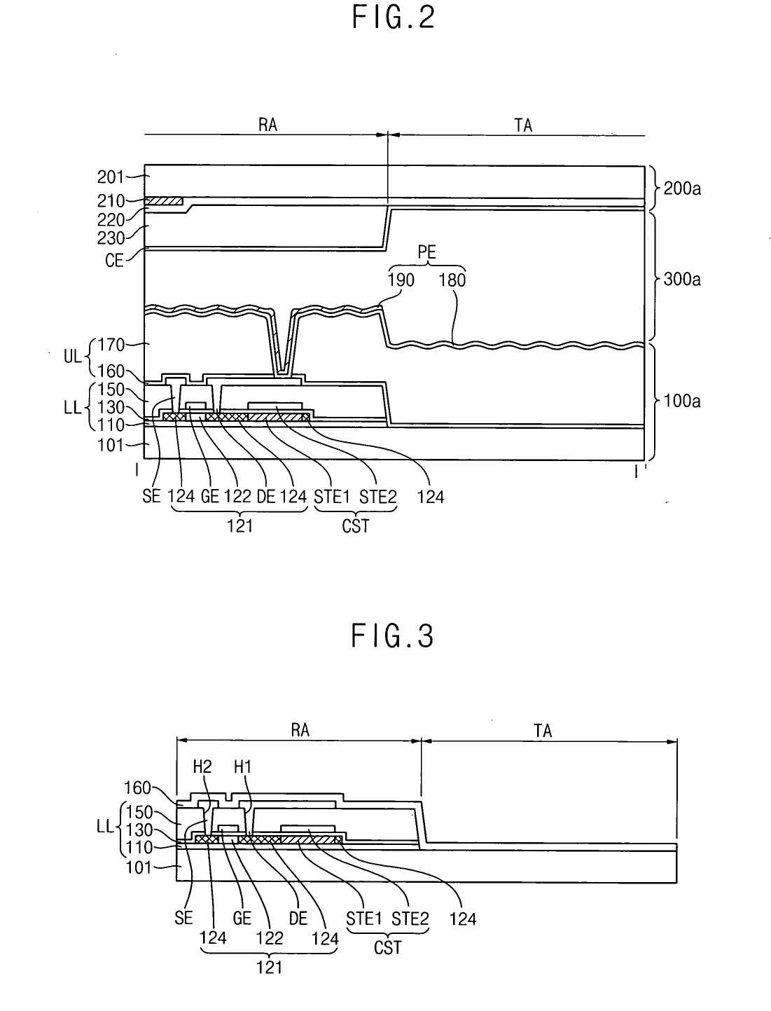

FIG. 1 is a plan view illustrating a display panel according to a first exemplary embodiment of the present invention. FIG. 2 is a cross-sectional view taken along a line I-I′ of FIG. 1.

Referring to FIGS. 1 and 2, the display panel includes an array substrate 100a and an opposite substrate 200a coupled to the array substrate 100a to receive a liquid crystal layer 300a. In the present exemplary embodiment, the display panel may be a transflective-type display panel.

The array substrate 100a includes a first base substrate 101, a gate line GL, a data line DL, a thin-film transistor (TFT) TR, a pixel electrode PE and a storage capacitor CST. The array substrate 100a may further include an alignment layer (not shown).

The gate line GL is formed from a gate metal film, and is extended along a first direction. The gate metal film may include an aluminum (Al) series metal such as aluminum, or aluminum alloy, a molybdenum (Mo) series metal such as molybdenum, and molybdenum alloy, and a metal including chromium (Cr), tantalum (Ta), titanium (Ti), tungsten (W), silver (Ag), copper (Cu), or an alloy thereof. The gate metal film may include a single-layer structure or a multilayer structure. For one example, the gate metal film may include molybdenum (Mo), molybdenum tantalum (MoTa), molybdenum tungsten (MoW) or aluminum nickel (AlNi). For another example, the gate metal film may include molybdenum (Mo), and aluminum (Al) that is sequentially formed on the molybdenum (Mo). For still another example, the gate metal film may include titanium (Ti), and aluminum (Al) that is sequentially formed on the titanium (Ti). For further still another example, the gate metal film may include molybdenum (Mo), aluminum (Al) that is sequentially formed on the molybdenum (Mo), and molybdenum (Mo) that is sequentially formed on the aluminum (Al).

The data line DL is formed from a source metal film, and is extended along a second direction crossing the first direction. The source metal film may include a copper (Cu) series metal such as copper (Cu), or a copper alloy, an aluminum (Al) series metal such as aluminum, or aluminum alloy, a silver (Ag) series metal such as silver, or silver alloy, a molybdenum (Mo) series metal such as molybdenum, or a molybdenum alloy, and a metal including chromium (Cr), tantalum (Ta), titanium (Ti), tungsten (W), or an alloy thereof. The source metal film may include a single-layer structure or a multilayer structure. For one example, the source metal film may include molybdenum (Mo), molybdenum tantalum (MoTa), molybdenum tungsten (MoW) or aluminum nickel (AlNi). For another example, the source metal film may include molybdenum (Mo) and aluminum (Al) that is sequentially formed on the molybdenum (Mo). For still another example, the gate metal film may include titanium (Ti), and aluminum (Al) that is sequentially formed on the titanium (Ti). For further still another example, the gate metal film may include molybdenum (Mo), aluminum (Al) that is sequentially formed on the molybdenum (Mo), and molybdenum (Mo) that is sequentially formed on the aluminum (Al). A blocking line (not shown) is formed below the data line DL, which is formed from the gate metal film, to be overlapped with the data line DL. The blocking line may transmit light that is incident from a rear surface of the first base substrate 101.

In one exemplary embodiment, the gate lines GL and the data lines DL adjacent to each other define a pixel P area; however, the pixel P area may also be otherwise defined. The pixel P area may include a reflective area RA reflecting light and a transmissive area TA transmitting light. For example, a transistor TR, a reflective electrode 190 electrically connected to the transistor TR, and a storage capacitor CST are formed in the reflective area RA. A transmissive electrode TE electrically connected to the transistor TR is formed in the transmissive area TA.

The transistor TR may include a polycrystalline silicon layer, a gate electrode GE, a source electrode SE and a drain electrode DE. The polycrystalline silicon layer 121 may include a channel portion 122 and a doping portion 124 doped with dopants at a high concentration. The gate electrode GE is electrically connected to the gate line GL and is formed on the channel portion. The source electrode SE is electrically connected to the data line DL and makes contact with the doping portion 124. The drain electrode DE is spaced apart from the source electrode SE to make contact with the doping portion 124. The drain electrode DE is electrically connected to the pixel electrode PE through a via hole VH.

The storage capacitor CST includes a first storage electrode STE1 formed from the polycrystalline silicon layer and a second storage electrode STE2 electrically connected to a storage line SL formed from the gate metal film. For example, the first storage electrode STE1 may be an area doped with dopants at a low concentration. Alternatively, the first storage electrode STE1 may be doped with dopants at a high concentration through an additional mask. Furthermore, the drain electrode DE may be extended to be overlapped with the second storage electrode STE2 on an upper portion of the storage capacitor CST.

The pixel electrode PE includes a reflective electrode portion 190 formed in the reflective area RA, and a transmissive electrode portion TE formed in the transmissive area TA. The reflective electrode portion 190 may include a reflective material. For one example, the reflective material may include an aluminum (Al) series metal such as aluminum, or aluminum alloy. For another example, the reflective material may include silver (Ag). The transmissive electrode portion TE may include an optically transparent and electrically conductive material. The optically transparent and electrically conductive material may include an oxide material or a nitride oxide material that includes at least one selected from the group consisting of indium (In), tin (Sn), zinc (Zn), aluminum (Al) and gallium (Ga).

The array substrate 100a includes a first insulation layer (which will be referred to hereinafter as a lower insulation layer LL) and a second insulation layer (which will be referred to as an upper insulation layer UL). The lower insulation layer LL includes a blocking layer 110 formed below the TFT TR, a gate insulation layer 130 and an insulation interlayer 150. The lower insulation LL is formed in the reflective area RA, and is not formed in the transmissive area TA.

The blocking layer 110 is formed between the first base substrate 101 and the polycrystalline silicon layer to prevent impurities from being applied from the first base substrate 101 toward the polycrystalline silicon layer. In this embodiment, the blocking layer 110 may perform a role of a heat-reservoir for a growth of silicon grains during a laser crystallizing. For example, when the blocking layer 110 includes the double layer structure, a lower layer of the blocking layer 110 is formed by oxide silicon (SiOx) and an upper layer of the blocking layer 110 is formed by nitride silicon (SiNx). Conventionally, the nitride silicon (SiNx) may decrease a light transmittance.

The gate insulation layer 130 may electrically isolate the polycrystalline silicon layer from the gate electrode and the second storage electrode STE2 that are formed on the polycrystalline silicon layer. The insulation interlayer 150 may electrically isolate the gate metal film from the source metal film. That is, the insulation interlayer 150 may electrically isolate the gate electrode GE from the source electrode SE and the drain electrode DE formed on the gate electrode GE.

The upper insulation layer UL includes a protective insulation layer 160 and an organic insulation layer 170. The upper insulation layer UL may be formed in the reflective area RA and the transmissive area TA.

The protective insulation layer 160 is formed on the source electrode SE, the drain electrode DE and the data line DL that are formed from the source metal film. The organic insulation layer 170 is formed on the protective insulation layer 160. An upper surface of the organic insulation layer 170 may include an embossed pattern. The protective insulation layer 160 may be omitted.

As a result, the lower insulation layer LL is not formed in the transmissive area TA, so that the transmittance of the pixel P may be increased. The advantageous effect of the improvement in light transmittance is described below.

The opposite substrate 200a includes a second base substrate 201, a light-blocking pattern 210, a color filter pattern 220, an overcoating layer 230 and a common electrode CE. The opposite substrate 200a may further include an alignment layer (not shown).

The light-blocking pattern 210 is formed on the second base substrate 201, and is formed in correspondence with the gate line GL and the data line DL.

The color filter pattern 220 is formed on the second base substrate 201 in correspondence with the pixel electrode PE. For example, the color filter pattern 220 may be a red color filter pattern among a red color filter pattern, a green color filter pattern and a blue color filter pattern. Because the pixel P has a structure in which the lower insulation layer LL is removed in correspondence with the transmissive area TA, a cell gap of the liquid crystal layer 300a is greater than that of the pixels having other color filter pattern. Therefore, the pixel P may have enhanced transmittance and color reproduction in a red color pixel, which corresponds to red light that has a wavelength relatively longer than light of other colors.

In a conventional pixel structure in which the lower insulation layer is not removed in a transmissive area of a red pixel, a luminance of red light was about 59.8 nits, and a luminance ratio of red light to white light was about 15.37%. Here, a luminance of a backlight applied to the conventional pixel structure is about 400 nits. However, in the pixel structure according to the exemplary embodiment in which the lower insulation layer is removed in the transmissive area of a red pixel, a luminance of red light was about 69.2 nits, and a luminance ratio of red light to white light was about 17.24%. Here, a luminance of a backlight applied to the pixel structure according to the exemplary embodiment is about 400 nits. Therefore, a luminance of the red light may be enhanced by about 16%, and the transmittance of the red light may be enhanced by about 12%.

The overcoating layer 230 is formed on the color filter pattern 220 in correspondence with the reflective area RA. A cell gap of the transmissive area TA is two times that of the reflective area RA due to the overcoating layer 230. That is, a multi-cell gap is defined in the display panel due to the overcoating layer 230. As the multi-cell gap is defined, the path of an external light that is reflected in the reflective area RA and emitted from a front side substantially identical to that of an internal light that is transmitted in the transmissive area TA and emitted from the front side.

The common electrode CE is formed on the second base substrate 201 formed on the overcoating layer 230.

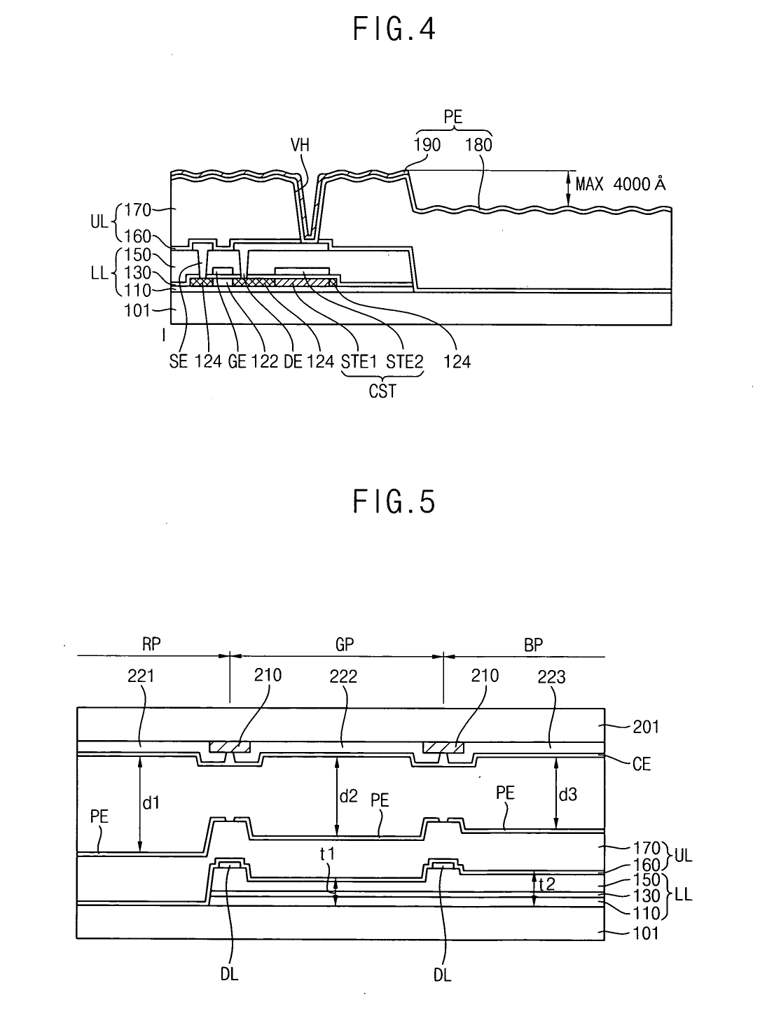

FIGS. 3 and 4 are cross-sectional views of an array substrate in order to illustrate a manufacturing process of the array substrate of FIG. 2.

Referring to FIGS. 1 and 3, the blocking layer 110 is formed on the first base substrate 101. The blocking layer 110 may have a multilayer structure having a lower layer and an upper layer. The lower layer may include silicon nitride (SiNx), and the upper layer may include silicon oxide (SiO2).

An amorphous silicon (a—Si) layer is formed on the first base substrate 101 having the blocking layer 110 formed thereon. For example, the amorphous silicon (a—Si) layer may be formed through low-pressure chemical vapor deposition (LPCVD), plasma-enhanced chemical deposition (PECVD), etc.

The amorphous silicon (a—Si) layer is crystallized to form the polycrystalline silicon layer. The polycrystalline silicon (poly-Si) layer is patterned to form the polycrystalline silicon pattern 121. The polycrystalline silicon (poly-Si) pattern 121 includes the channel portion 122 and doping portion 124 of the transistor TR, and a first storage electrode STE of the storage capacitor CST.

The doping portion 124 may be an area doped with dopants at a high concentration, and the storage electrode STE1 may be an area doped with dopants at a low concentration. Alternatively, the first storage electrode STE1 may be doped with dopants at a high concentration though an additional mask.

The gate insulation layer 130 is formed on the first base substrate 101 having the polycrystalline silicon layer 121 formed thereon. For example, the gate insulation layer 130 may include tetraethyl orthosilicate (TEOS).

The gate metal pattern formed from a gate metal film is formed on the gate insulation layer 130. The gate metal pattern may include the gate electrode GE, the gate line GL, the storage line SL and the second storage electrode STE2.

The gate electrode GE is formed on gate insulation layer 130 in correspondence with the channel portion 122, and the second storage electrode STE2 is formed on the gate insulation layer 130 to overlap with the first storage electrode STE1.

The insulation interlayer 150 is formed on the first base substrate 101 having the gate metal pattern formed thereon. Although not shown in the figures, insulation interlayer 150 may include a multilayer structure having a lower layer and an upper layer. The lower layer may include a silicon oxide (SiO2), and the upper layer may include silicon nitride (SiNx).

The insulation interlayer 150 and the gate insulation layer 130 are etched to form first and second contact holes H1 and H2 that expose the doping portion 124. Moreover, the insulation interlayer 150, the gate insulation layer 130 and the blocking layer 110 in correspondence with the transmissive area TA are etched to expose the first base substrate 101.

Accordingly, the lower insulation layer LL which includes silicon nitride that decreases transmittance, which is initially formed in the transmissive area TA is removed from transmissive area TA so that the light transmittance of the pixel P may be enhanced.

A source metal pattern is formed on the first base substrate 101 having the first and second contact holes H1 and H2 formed thereon. The source metal pattern may include a single-layer structure or a multilayer structure. For one example, the source metal pattern may include molybdenum (Mo), molybdenum tantalum (MoTa), molybdenum tungsten (MoW) or aluminum nickel (AlNi). For another example, the source metal pattern may include molybdenum (Mo) and aluminum (Al) that is sequentially formed on the molybdenum (Mo). For still another example, the source metal pattern may include titanium (Ti), and aluminum (Al) that is sequentially formed on the titanium (Ti). For further still another example, the source metal pattern may include molybdenum (Mo), aluminum (Al) that is sequentially formed on the molybdenum (Mo), and molybdenum (Mo) that is sequentially formed on the aluminum (Al).

The source metal pattern may include the source and drain electrodes SE and DE, respectively, and the data line DL. The source and drain electrodes SE and DE make contact with the doping portion 124 through the first and second contact holes H1 and H2. The data line GL may cross the gate line GL to be connected to the source electrode SE. For example, the drain electrode DE is extended to cover the second storage electrode STE2.

The protective insulation layer 160 is formed on the first base substrate 101 having the source metal pattern. The protective insulation layer 160 may include silicon nitride (SiNx). The protective insulation layer 160 is formed on the first base substrate 101 to make contact with the first base substrate 101 in correspondence with the transmissive area TA.

Referring to FIGS. 1 and 4, the organic insulation layer 170 is formed on the first base substrate 101 having the protective insulation layer 160 formed thereon. The organic insulation layer 170 may include an organic insulation material. Thus, the upper insulation layer UL is formed on the first base substrate 101.

Then, the organic insulation layer 170 and the protective insulation layer 160 are etched to form a via hole VH that exposes the drain electrode DE. Also as illustrated in FIG. 4, an embossed pattern is formed on an upper portion of the organic insulation layer 170. Alternatively, the embossed pattern may be only formed in the reflective area RA.

An optically transparent and electrically conductive material is formed on the first base substrate 101 having the via hole VH formed thereon. The optically transparent and electrically conductive material make contact with the drain electrode DE through the via hole VH. The optically transparent and electrically conductive material may include an oxide material or a nitride oxide material that includes at least one selected from the group consisting of indium (In), tin (Sn), zinc (Zn), aluminum (Al) and gallium (Ga). The optically transparent and electrically conductive material is patterned to form the transmissive electrode 180 in the pixel area.

Then, a reflective material is formed on the first base substrate 101 having the transmissive electrode 180 formed thereon. The reflective material includes an aluminum (Al) series metal such as aluminum, or an aluminum alloy. The reflective material is patterned to form the reflective electrode 190 in the reflective area RA. Therefore, the transmissive electrode 180 is formed in the transmissive area TA, and the reflective electrode 190 is formed in the reflective area RA.

The embossed pattern is formed on the upper portion of the organic insulation layer 170, so that the reflective electrode 190 also has an embossed pattern. The embossed pattern may enhance a reflection ratio.

As described above, the pixel P has a structure in which the lower insulation layer LL is removed in the transmissive area TA, so that a step difference of the maximum 4,000 Å is formed between the reflective area RA and the transmissive area TA. A cell gap of the pixel P corresponding to the transmissive area TA is relatively greater than that of other pixels corresponding to the transmissive area TA. Therefore, the pixel P may have enhanced transmittance and color reproduction in a red color pixel corresponding to red light that has a wavelength relatively longer than light of other colors.

### Exemplary Embodiment 2

### A Display Panel

FIG. 5 is a cross-sectional view schematically illustrating a display panel according to a second exemplary embodiment of the present invention.

Referring to FIG. 5, the display panel includes a red color pixel RP having a red color filter pattern 221 formed thereon, a green color pixel GP having a green color filter pattern 222 formed thereon, and a blue color pixel BP having a blue color filter pattern 223 formed thereon.

The lower insulation layer LL is removed in the transmissive area of the red color pixel RP, and the upper insulation layer UL is formed on the first base substrate 101. The lower insulation layer LL includes the blocking layer 110, the gate insulation layer 130 and the insulation interlayer 150. Therefore, a cell gap corresponding to the red color filter pixel RP is a first cell gap ‘d1’.

The lower insulation layer LL of a first thickness t1 is formed in the transmissive area of the green color pixel GP. For example, the blocking layer 110 and the gate insulation layer 130 are formed on the first base substrate 101, and the insulation interlayer 150 formed on the gate insulation layer 130 is removed a predetermined thickness using a slit mask or a half-tone mask. Therefore, a cell gap corresponding to the green pixel GP is a second cell gap ‘d2’ that is smaller than the first cell gap ‘d1’.

The lower insulation layer LL of the second thickness t2 that is thicker than the first thickness ‘d1’ is formed in the transmissive area of the blue color pixel BP. For example, the blocking layer 110 and the gate insulation layer 130 are formed on the first base substrate 101, and the insulation interlayer 150 formed on the gate insulation layer 130 is removed to have a thinner thickness than the thickness of the insulation interlayer of the green color pixel GP using a slit mask or a half-tone mask. Therefore, a cell gap corresponding to the blue color pixel BP is a third cell gap ‘d3’ that is smaller than the second cell gap ‘d2’.

The lower insulation layer LL is differentially removed with respect to the red, green and blue color pixels RP, GP and BP. Comparing to wavelengths of red, green and blue lights, the wavelength of the red light is longer than other color lights, and the wavelength of the blue light is shorter than other color lights. Therefore, a thickness of the lower insulation layer LL is differentially formed based on the color light characteristics, so that the transmittance of the display panel according to the present invention may be enhanced.

In the above explanation, the thickness of the lower insulation layer LL is differentially formed to differentially form cell gaps of the red, green and blue color pixels RP, GP and BP. However, a thickness of the organic insulation layer 170 that is relatively thicker than other layers may be differentially formed to differentially form cell gaps of the red, green and blue color pixels RP, GP and BP to each other.

For example, in order to form the red color pixel RP, the lower insulation layer LL is removed, and the upper insulation layer UL is retained. Thus, the red color pixel RP may have the first cell gap ‘d1’. Alternatively, in order to form the green color pixel GP, the lower insulation layer LL is remaining and the upper insulation layer UL is removed a predetermined thickness using a slit mask or a half-tone mask. Thus, the green color pixel GP may have the second cell gap ‘d2’ that is thinner than the first cell gap ‘d1’.

Furthermore, in order to form the blue color pixel BP, the lower insulation layer LL is remaining, and the upper insulation layer UL is removed by a predetermined thickness that is thinner than the upper insulation layer UL of the green color pixel GP using a slit mask or a half-tone mask. Alternatively, in order to form the blue color pixel BP, the lower insulation layer LL and the upper insulation layer UL may be remaining. Thus, the blue color pixel BP may have a third cell gap ‘d3’ that is thinner than the second cell gap ‘d2’. Accordingly, the upper insulation layer UL of the red color pixel RP may have a first thickness, and the upper insulation layer UL of the green color pixel GP may have a second thickness that is thinner than the first thickness. Moreover, the upper insulation layer UL of the blue color pixel BP may have a third thickness that is thicker than the second thickness.

### Exemplary Embodiment 3

### A Display Panel

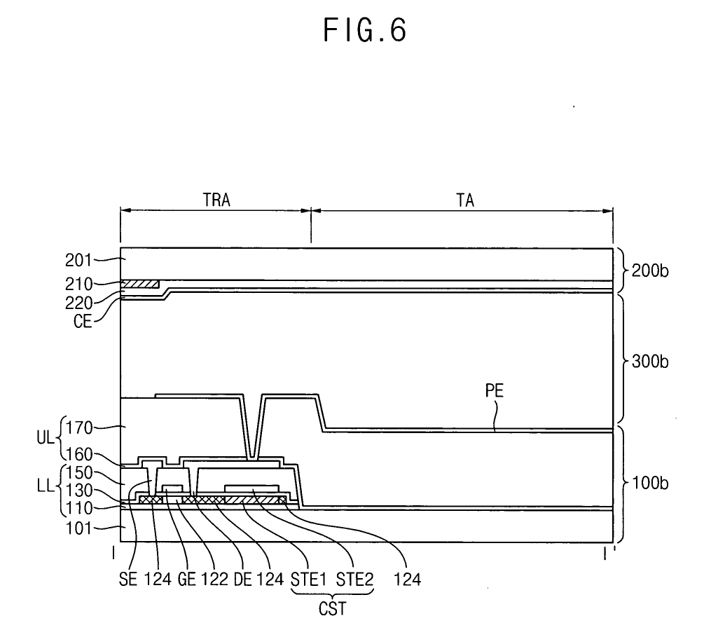

FIG. 6 is a cross-sectional view illustrating a display panel according to a third exemplary embodiment of the present invention.

Referring to FIG. 6, the display panel is a transmissive-type display panel that includes an array substrate 100b, an opposite substrate 200b and a liquid crystal layer 300b.

The array substrate 100b includes a first base substrate 101 as described in FIGS. 1 and 2. In one exemplary embodiment, a plurality of gate lines GL and a plurality of data lines DL define pixel P area on the first base substrate 100; however, the pixel P area may be otherwise defined.

The pixel P area may include a transistor area TRA having a transistor TR formed thereon, and a transmissive area TA having a pixel electrode PE formed thereon. The pixel electrode PE is a transmissive electrode formed from an optically transparent and electrically conductive material.

The transistor TR and a storage capacitor CST, which include a lower insulation layer LL, are formed in the transistor area TRA. An upper insulation layer UL is formed on the transistor TR and a storage capacitor CST.

For example, the transistor TR includes a polycrystalline silicon layer, a gate electrode GE, a source electrode SE and a drain electrode DE. The polycrystalline silicon layer may include a channel portion 122 and a doping portion 124 doped with dopants at a high concentration. The gate electrode GE is formed on the channel portion. The source electrode SE makes contact with the doping portion 124. The drain electrode DE is spaced apart from the source electrode SE to make contact with the doping portion 124.

The lower insulation layer LL includes a blocking layer 110, a gate insulation layer 130 and an insulation interlayer 150. The blocking layer 110 is formed between the first base substrate 101 and the polycrystalline silicon layers 122 and 124. The gate insulation layer 130 is formed between the polycrystalline silicon layers 122 and 124 and the gate electrode GE. The insulation interlayer 150 is formed between the gate electrode GE and the source and drain electrodes SE and DE.

The storage capacitor CST includes a first storage electrode STE1 and a second storage electrode STE2. The first storage electrode STE1 is formed from the polycrystalline silicon layers 122 and 124, and is doped with dopants at a low concentration. The second storage electrode STE2 is electrically connected to a storage line SL formed from the gate metal film. As shown in FIG. 6, the drain electrode DE may be extended to cover the second storage electrode STE2.

The upper insulation layer UL includes a protective insulation layer 160 formed on the source and drain electrodes SE and DE, and an organic insulation layer 170 formed on the protective insulation layer 160.

The upper insulation layer UL and the pixel electrode PE are formed in the transmissive area TA. The upper insulation layer UL is directly formed on the first base substrate 101 corresponding to the transmissive area TA. The pixel electrode PE makes contact with the drain electrode through a via hole VH to be formed in correspondence with the transmissive area TA.

As a result, the lower insulation layer LL is removed in the transmissive area TA, and the upper insulation layer UL is formed in the transmissive area TA. Therefore, insulation layers are removed, which are formed from silicon nitride (SiNx) that decreases transmittance in the transmissive area TA, so that transmittance may be enhanced.

The opposite substrate 200b includes a second base substrate 201, a blocking pattern 210, a color filter pattern 220 and a common electrode CE. The opposite substrate 200b does not require the overcoating layer 230 as shown in FIG. 2, in order to realize the liquid crystal layer 300b of a unit cell gap. For example, the color filter pattern 220 is a red color filter pattern transmitting red light that has a wavelength relatively longer than light of other colors.

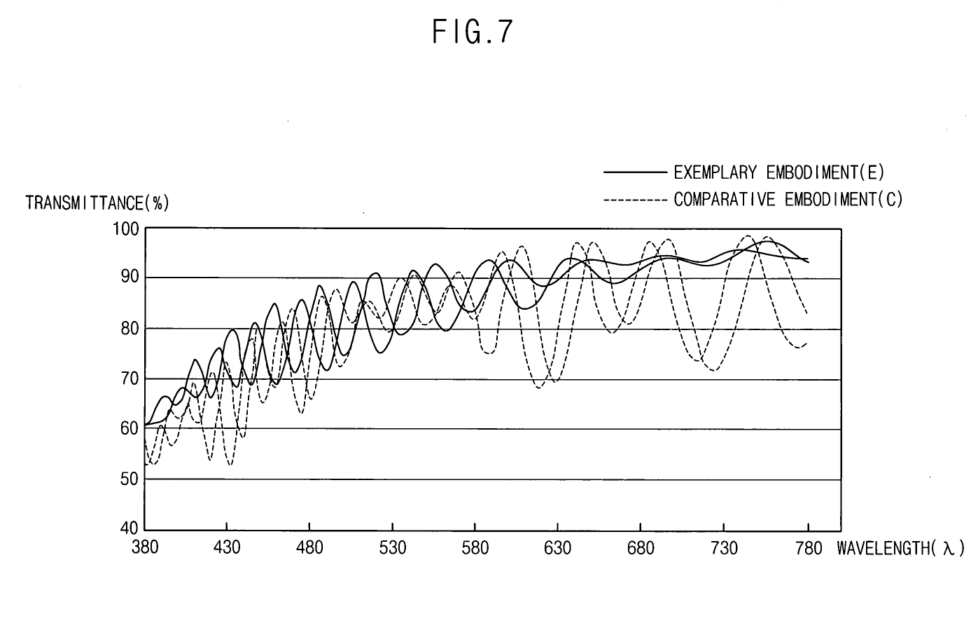

FIG. 7 is a plot showing light transmittances of array substrates according to an exemplary embodiment of the present invention and a comparative embodiment of the present invention.

In FIG. 7, an Exemplary Embodiment ‘E’ represents the transmittance of the array substrate when the lower insulation layer is removed, which is formed in a transmissive area of a red color pixel, and a Comparative Embodiment ‘C’ represents the transmittance of the array substrate when the lower insulation layer is not removed, which is formed in a transmissive area of a red color pixel.

Referring to FIG. 7, it can be noted that the transmittance of the Exemplary Embodiment ‘E’ was enhanced by about 5% to about 10% with respect to that of the Comparative Embodiment ‘C’. Moreover, it can be seen that a ripple component of the Exemplary Embodiment ‘E’ was decreased with respect to that of the Comparative Embodiment ‘C’.

Accordingly, the lower insulation layer corresponding to the transmissive area of the pixel is removed, so that the transmittance may be enhanced.

As described above, according to the present invention, a lower insulation layer may decrease the transmittance of an array substrate, so that the transmittance may be enhanced. The lower insulation layer may include a blocking layer formed between a base substrate and a polycrystalline silicon layer, a gate insulation layer formed between the polycrystalline silicon layer and a gate electrode, and an insulation interlayer formed between the gate electrode and a source electrode. That is, an insulation layer including silicon nitride (SiNx) is removed, so that the transmittance of the array substrate may be enhanced.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An array substrate comprising:
a substrate having a first surface;
a first insulation layer formed on a first portion of the first surface;
a transistor formed in correspondence with the first insulation layer;
a pixel electrode electrically connected to the transistor; and
a second insulation layer having a first portion on the transistor and a second portion directly contacting the first surface of the substrate in an area adjacent to the transistor.

2. The array substrate of claim 1, wherein the transistor comprises:
a polysilicon layer on the base substrate, the polysilicon layer including a channel portion and a doped portion;
a gate electrode on the channel portion; and
source and drain electrodes in contact with the doped portion.

3. The array substrate of claim 2, wherein the second insulation layer comprises:
a protective insulation layer formed on the source and drain electrodes; and
an organic insulation layer formed on the protective insulation layer.

4. The array substrate of claim 2, wherein the first insulation layer comprises:
a blocking layer interposed between the first surface of substrate and the polysilicon layer;
a gate insulation layer formed between the polysilicon layer and the gate electrode; and
an insulation interlayer formed between the gate electrode and the source and drain electrodes.

5. The array substrate of claim 4, wherein the blocking layer and the insulation interlayer comprise silicon nitride.

6. The array substrate of claim 4, further comprising:
a first storage electrode formed from the polysilicon layer; and
a storage capacitor including a second storage electrode on the gate insulation layer corresponding to the first storage electrode.

7. The array substrate of claim 1, wherein the pixel electrode is formed from an optically transparent and electrically conductive material,
the pixel electrode comprises a reflective electrode formed in a reflective area, and a transmissive electrode formed in a transmissive area,
the second insulation layer is positioned on the first insulation layer in correspondence with the reflective electrode and the second insulation layer directly contacts the first surface of substrate in correspondence with the transmissive area.

8. A display panel comprising:
an array substrate comprising:
a substrate having a first surface;
a first insulation layer formed on a first portion of the first surface;
a transistor formed in correspondence with the first insulation layer;
a pixel electrode electrically connected to the transistor; and
a second insulation layer having a first portion on the transistor and a second portion directly contacting the first surface in an area adjacent to the transistor; and
an opposite substrate coupled to the array substrate to receive a liquid crystal layer.

9. The display panel of claim 8, wherein the transistor comprises:
a polysilicon layer on the base substrate, the polysilicon layer including a channel portion and a doped portion;
a gate electrode on the channel portion; and
source and drain electrodes in contact with the doped portion.

10. The display panel of claim 9, wherein the second insulation layer comprises:
a protective insulation layer formed on the source and drain electrodes; and
an organic insulation layer formed on the protective insulation layer.

11. The display panel of claim 9, wherein the first insulation layer comprises:
a blocking layer interposed between the first surface of substrate and the polysilicon layer;
a gate insulation layer formed between the polysilicon layer and the gate electrode; and
an insulation interlayer formed between the gate electrode and the source and drain electrodes.

12. The display panel of claim 11, further comprising:
a first storage electrode formed from the polysilicon layer; and
a storage capacitor including a second storage electrode on the gate insulation layer corresponding to the first storage electrode.

13. The display panel of claim 8, wherein the pixel electrode is formed from an optically transparent and electrically conductive material,
the pixel electrode comprises a reflective electrode portion positioned in a reflective area and a transmissive electrode portion positioned in a transmissive area,
and the second insulation layer is positioned on the first insulation layer in correspondence with the reflective electrode and the second insulation layer directly contacts the first surface in correspondence with the transmissive area.

14. The display panel of claim 8, wherein the opposite substrate comprises a color filter pattern formed in correspondence with an area where the pixel electrode is formed.

15. The display panel of claim 14, wherein the color filter pattern comprises a red color filter pattern.

16. The display panel of claim 15, wherein the opposite substrate further comprises a green color filter pattern and a blue color filter pattern.

17. The display panel of claim 16, wherein the second insulation layer has a first thickness in correspondence with the green color filter pattern, and the second insulation layer has a second different thickness in correspondence with the blue color filter pattern.

18. The display panel of claim 16, wherein a cell gap of the red color filter is relatively greater than that of other color filter, and a cell cap of the blue color filter is relatively smaller than that of other color filter.
